(19) United States
(12) Patent Application Publication
(10) Pub. No.: US 2009/0273747 A1
(43) Pub. Date: Nov. 5, 2009

(54) LIQUID CRYSTAL DISPLAY AND METHOD FOR MANUFACTURING THE SAME

(76) Inventors: KYOUNG-JU SHIN, Hwaseong-si (KR); Cheol-Woo Park, Suwon-si (KR); Chang-Hoon Kim, Cheonan-si (KR); Chang-Soon Jang, Seoul (KR)

Correspondence Address: F. CHAU & ASSOCIATES, LLC, 130 WOODBURY ROAD, WOODBURY, NY, 11797, US

(21) Appl. No.: 12/424,668

(22) Filed: Apr. 16, 2009

(30) Foreign Application Priority Data
Apr. 30, 2008 (KR) 10-2008-0040512

(51) Int. Cl. G02F 1/1335; G02F 1/1339; H01L 21/02

(52) U.S. Cl. 349/107; 349/155; 438/30; 257/E21.02

(57) ABSTRACT

A liquid crystal display and a manufacturing method thereof, including: a first substrate; a thin film transistor formed on the first substrate; a pixel electrode connected to the thin film transistor; a second substrate facing the first substrate; a first spacer formed on the second substrate and overlapping the thin film transistor; a second spacer formed on the second substrate and overlapping the pixel electrode; a common electrode formed on the second substrate, the first spacer, and the second spacer; and a liquid crystal layer disposed between the first substrate and the second substrate, wherein the pixel electrode and the common electrode disposed on the second spacer form a storage capacitor.

### CROSS-REFERENCE TO RELATED APPLICATION

This application claims priority to and the benefit of Korean Patent Application No. 10-2008-0040512 filed in the Korean Intellectual Property Office on Apr. 30, 2008, the entire contents of which are incorporated herein by reference.

### BACKGROUND

(a) Technical Field

The present disclosure relates to a liquid crystal display and a manufacturing method thereof.

(b) Discussion of Related Art

A liquid crystal display (LCD) has become one of the most commonly used flat panel displays, and it includes two substrates with electrodes formed thereon and a liquid crystal layer interposed between the two substrates. In the LCD, a voltage is applied to the electrodes to realign liquid crystal molecules of the liquid crystal layer to thereby regulate the transmittance of light passing through the liquid crystal layer.

Among various LCD constructions, an LCD having a structure in which field generating electrodes are respectively formed on two display panels is widely used. Among the two display panels, a plurality of pixel electrodes and thin film transistors are arranged in a matrix format on one display panel hereinafter referred to as a “thin film transistor array panel”. Color filters of red, green, and blue are formed on the other display panel, hereinafter referred to as a “common electrode panel”, and one common electrode covers the entire surface of common electrode panel.

In this liquid crystal display, the pixel electrode and the common electrode, along with the liquid crystal layer interposed therebetween, form a liquid crystal capacitor and the liquid crystal capacitor maintains the applied voltage after the thin film transistor is turned off.

Additionally, the liquid crystal display may her include a storage capacitor for reinforcing the capacity for maintaining the voltage of the liquid crystal capacitor, and the storage capacitor may be formed by an overlap between the pixel electrode and a storage electrode formed with the same layer as a signal line, such as a gate line.

The storage electrode is made of an opaque metal, however, such that the aperture ratio may be deteriorated by the area occupied with the storage electrode. Also, when an organic layer is formed between the storage electrode and the pixel electrode, the distance between the storage electrode and the pixel electrode is large such that the storage capacitance may be decreased.

The above information disclosed in this Background section is only for enhancement of understanding of the background of the invention and therefore it may contain information that does not form the prior art that is already known in this country to a person of ordinary skill in the art.

### SUMMARY OF THE INVENTION

Accordingly, exemplary embodiments of the present invention reduce the area occupied by the storage electrode in the display area thereby to increase the aperture ratio and simultaneously to increase the storage capacitance.

A liquid crystal display according to an exemplary embodiment of the present invention includes: a first substrate; a thin film transistor formed on the first substrate; a pixel electrode connected to the thin film transistor; a second substrate facing the first substrate; a first spacer formed on the second substrate and overlapping the thin film transistor; a second spacer formed on the second substrate and overlapping the pixel electrode; a common electrode formed on the second substrate, the first spacer, and the second spacer; and a liquid crystal layer disposed between the first substrate and the second substrate, wherein the pixel electrode and the common electrode disposed on the second spacer form a storage capacitor.

The pixel electrode and the common electrode disposed on the second spacer may be spaced apart from each other by a distance in the range of 0.1 to 0.3 μm.

The liquid crystal display may further include a first alignment layer formed on the pixel electrode and a second alignment layer formed on the common electrode, wherein the first alignment layer may contact the second alignment layer where it is disposed on the first spacer.

The liquid crystal display may include a first pixel a second pixel, and a third pixel displaying different colors, and the first spacer is formed in at least one of the first pixel, the second pixel, and the third pixel.

The first pixel the second pixel, and the third pixel may respectively include a first color filter, a second color filter, and a third color filter, and at least one of the first color filter, the second color filter, and the third color filter has a different thickness from the others.

The first color filter may be the thickest, and the second spacer of the first pixel may have a lesser height than that of the second spacers of the second pixel and the third pixel.

The first color filter may be the thickest, and the height of the second spacers of the first pixel the second pixel and the third pixel may be the same.

The first color filter, the second color filter, and the third color filter may be progressively thicker, and the widths of the second spacers may be progressively increased according to the sequence of the second spacer of the third pixel, the second spacer of the second pixel, and the second spacer of the first pixel.

One spacer among the second spacers of the first pixel the second pixel, and the third pixel may have a different height from the others.

The first pixel may be a blue pixel the second pixel may be a green pixel and the third pixel may be a red pixel.

A manufacturing method of a liquid crystal display according to an exemplary embodiment of the present invention includes: forming a thin film transistor and a pixel electrode on a first substrate; forming a first spacer overlapping the thin film transistor and a second spacer overlapping the pixel electrode on the second substrate; forming a common electrode on the first spacer and the second spacer; combining the first substrate and the second substrate; and forming a liquid crystal layer between the first substrate and the second substrate.

The first spacer and the second spacer may have different heights.

The first spacer and the second spacer may be formed with the different heights by using halftone exposure or a slit mask.

The method may further include forming first, second, and third color filters on the second substrate before forming the first spacer and the second spacer, wherein at least one of the first, second, and third color filters has a different thickness from the others.

The first color filter may be the thickest, and the second spacers on the first, second, and third color filters may have the same height.

The first color filter may be the thickest, and the second spacer on the first color filter may be formed with a different height from that of the second spacers on the second and third color filters.

The thicknesses may become thicker in the sequence of the first color filter, the second color filter, and the third color filter, and the width of the second spacers may become larger in the sequence of the second spacer on the third color filter, the second spacer on the second color filter, and the second spacer on the first color filter.

The first color filter may be a blue filter, the second color filter may be a green filter, and the third color filter may be a red filter.

The storage capacitor is formed between the pixel electrode and the common electrode such that the aperture ratio is increased and good storage capacitance may be obtained compared with the case of having an additional storage electrode.

### BRIEF DESCRIPTION OF THE DRAWINGS

FIG. 1 is a layout view showing three pixels continuously disposed in a liquid crystal display according to an exemplary embodiment of the present invention.

FIG. 2 is a cross-sectional view of the liquid crystal display shown in FIG. 1 taken along the line II-II.

FIG. 3 is a layout view of a liquid crystal display according to an exemplary embodiment of the present invention.

FIG. 4 is a cross-sectional view of the liquid crystal display shown in FIG. 3 taken along the line IV-IV.

FIG. 5 is a layout view of a liquid crystal display according to an exemplary embodiment of the present invention.

FIG. 6 is a cross-sectional view of the liquid crystal display shown in FIG. 5 taken along the line VI-VI.

FIG. 7 is a layout view of a liquid crystal display according to an exemplary embodiment of the present invention.

FIG. 8 is a cross-sectional view of the liquid crystal display shown in FIG. 7 taken along the line VIII-VIII.

FIG. 9 is a layout view of a liquid crystal display according to an exemplary embodiment of the present invention.

FIG. 10 is a cross-sectional view of the liquid crystal display shown in FIG. 9 taken along the line XI-XI.

### DETAILED DESCRIPTION OF EXEMPLARY EMBODIMENTS

The present invention will be described more fully hereinafter with reference to the accompanying drawings, in which exemplary embodiments of the invention are shown. As those of ordinary skill in the art would realize, the described exemplary embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

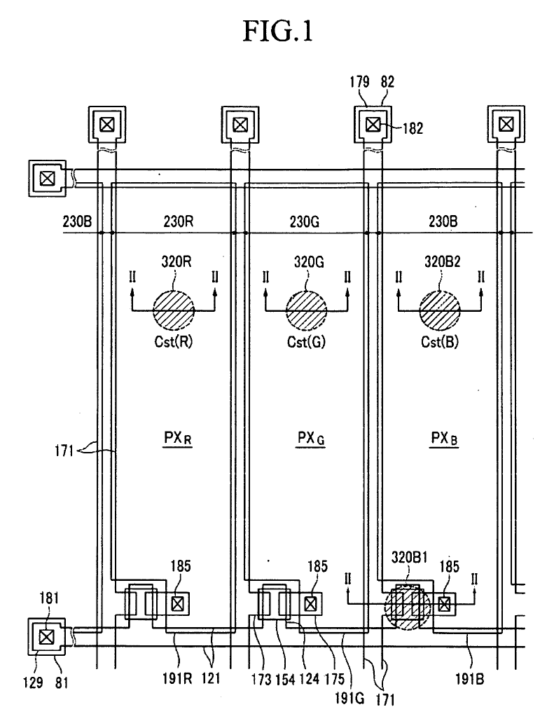

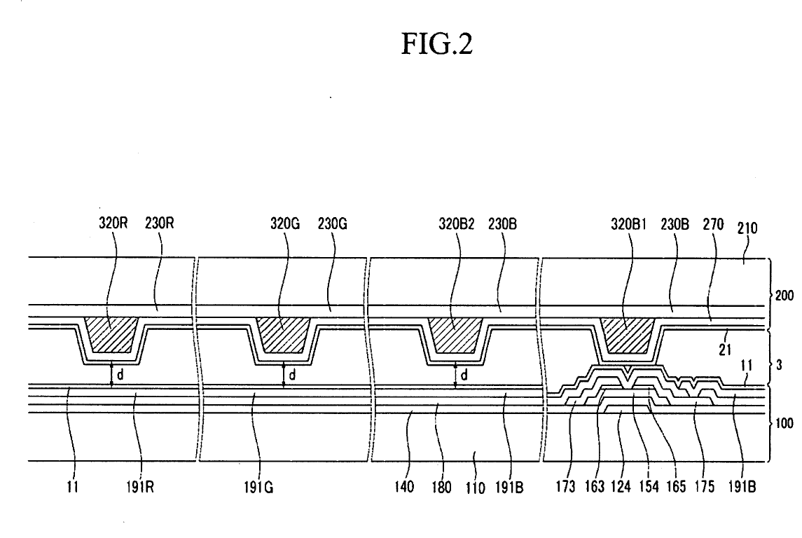

Now, a liquid crystal display according to an exemplary embodiment of the present invention will be described in detail with reference to FIG. 1 and FIG. 2.

FIG. 1 is a layout view showing three pixels continuously disposed in a liquid crystal display according to an exemplary embodiment of the present invention, and FIG. 2 is a cross-sectional view of the liquid crystal display shown in FIG. 1 taken along the lines II-II.

Referring to FIG. 1 and FIG. 2, the liquid crystal display according to an exemplary embodiment of the present invention includes a thin film transistor array panel 100 and a common electrode panel 200 facing each other, with a liquid crystal layer 3 disposed therebetween.

The liquid crystal display includes a red pixel PX_{R}, a green pixel PX_{G}, and a blue pixel PX_{B} displaying different respective colors and that are continuously disposed.

Initially, the thin film transistor array panel 100 will be described.

A plurality of gate lines 121 for transmitting gate signals is formed on an insulating substrate 110. Each gate line 121 includes a plurality of gate electrodes 124 extending upward and an end portion 129 having a wide width for connection to an external circuit.

A gate insulating layer 140 preferably made of silicon nitride (SiNx) or silicon oxide (SiO2) is formed on the gate lines 121.

A plurality of semiconductor islands 154 preferably made of amorphous or crystallized silicon is formed on the gate insulating layer 140, and a plurality of ohmic contact islands 163 and 165 preferably made of a material such as n+ hydrogenated amorphous silicon in which an n-type impurity such as phosphor is doped with a high density, or of silicide, is formed on the semiconductor islands 154.

A plurality of data lines 171 and drain electrodes 175 is formed on the ohmic contacts 163 and 165 and the gate insulating layer 140.

The data lines 171 transfer data signals and substantially extend in a longitudinal direction, thereby intersecting the gate lines 121. Each data line 171 includes a plurality of source electrodes 173 extending toward the drain electrodes 175, and a source electrode 173 and a drain electrode 175 forming a pair are disposed opposite to each other on the gate electrode 124.

One gate electrode 124, one source electrode 173, and one drain electrode 175 form a thin film transistor (TFT) together with the semiconductor island 154, and a channel of the TFT is formed at the semiconductor island 154 between the source electrode 173 and the drain electrode 175.

A passivation layer 180 is formed on the data lines 171 and the drain electrodes 175. The passivation layer 180 has a plurality of contact holes 182 and 185 respectively exposing end portions 179 of the data lines 171, and the drain electrodes 175, and the passivation layer 180 and the gate insulating layer 140 have a plurality of contact holes 181 exposing the end portions 129 of the gate lines 121.

A plurality of pixel electrodes 191R, 191G, and 191B and a plurality of contact assistants 81 and 82 are formed on the passivation layer 180.

The pixel electrodes 191R, 191G, and 191B are connected to the drain electrodes 175 through the contact holes 185, thereby receiving data voltages from the drain electrodes 175.

The contact assistants 81 and 82 are connected with the end portions 129 of the gate lines 121 and the end portions 179 of the data fines 171 via the contact holes 181 and 182, respectively. The contact assistants 81 and 82 complement adhesion of the end portions 129 of the gate lines 121 and the end portions 179 of the data lines 171 with an external device (not shown), and protect the end portions.

The common electrode panel 200 will now be described.

A plurality of light blocking members (not shown) that are separated from each other by a predetermined interval and are called a black matrix is formed on an insulation substrate 210 of the common electrode panel 200. The light blocking members may, however, be formed in the thin film transistor array panel 100.

Color filters 230R, 230G, and 230B are formed on the light blocking members and the substrate 210 in each pixel PX_{R}, PX_{G}, and PX_{B}.

Column spacers 320R, 320G, 320B1, and 320B2 are formed on the color filters 230R, 230G, and 230B.

The column spacers 320R, 320G, 320B1, and 320B2 include a main spacer 320B1 overlapping the thin film transistor, and sub-spacers 320R, 320G, and 320B2 overlapping the pixel electrodes 191R, 191G, and 191B.

The main spacer 320B1 is disposed in at least one pixel of the red pixel PX_{R}, the green pixel PX_{G}, and the blue pixel PX_{B}, thereby maintaining a cell gap between the thin film transistor array panel 100 and the common electrode panel 200. In the exemplary embodiment shown in FIG. 1, the main spacer 320B1 is formed in only the blue pixel PX_{B}, however, it may be disposed at a position overlapping the thin film transistor of the red pixel PX_{R} or the green pixel PX_{G} as well as the blue pixel PX_{B}.

The sub-spacers 320R, 320G, and 320B2 have substantially the same height as the main spacer 320B1, and as described in the following, storage capacitors may be formed between the pixel electrodes 191R, 191G, and 191B of each pixel PX_{R}, PX_{G}, and PX_{B}, and a common electrode 270.

The common electrode 270 is formed on the column spacers 320R, 320G, and 320B and the color filters 230R, 230G, and 230B.

A first alignment layer 11 and a second alignment layer 21 are respectively formed on the inner surfaces of the thin film transistor array panel 100 and the common electrode panel 200, however, one of the two may be omitted.

The liquid crystal layer 3 including a plurality of liquid crystal molecules (not shown) is formed between the thin film transistor array panel 100 and the common electrode panel 200. The liquid crystal molecules of the liquid crystal layer 3 are rearranged by an electric field generated between the common electrode 270 and the pixel electrodes 191R, 191G, and 191B, and a liquid crystal capacitor is formed therebetween.

As described above, in the liquid crystal display according to an exemplary embodiment of the present invention, the spacers include the main spacer 320B1 overlapping the thin film transistor and the sub-spacers 320R, 320G, and 320B2 formed at the positions overlapping the pixel electrodes 191R, 191G, and 191B.

The main spacer 320B1 and the sub-spacers 320R, 320G, and 320B2 have substantially the same height, however, the thin film transistor array panel 100 and the common electrode panel 200 contact the main spacer 320B1 by a step of the thin film transistor in a region where the main spacer 320B1 is formed. Accordingly, the distance between the thin film transistor array panel 100 and the common electrode panel 200 may be maintained by the main spacer 320B1.

The common electrode 270 and the pixel electrodes 191 that are disposed on the sub-spacers 320R, 320G, and 320B2 form storage capacitors via the first and second alignment layers 11 and 21 acting as insulators. Each storage capacitor serves as an auxiliary to the liquid crystal capacitor to enhance the voltage storage capacity of the liquid crystal capacitor. Accordingly, it is not necessary to form an additional storage electrode for the storage capacitor in the display area, whereby the aperture ratio may be prevented from being reduced by the area occupied by such an additional storage electrode.

In this exemplary embodiment, the common electrode 270 and the pixel electrodes 191 that are disposed on the sub-spacers 320R, 320G, and 320B2 are spaced apart from each other by a predetermined distance d. The predetermined distance d may be in the range of about 0.1 to 0.3 μm.

The pixel electrodes 191R, 191G, and 191B and the common electrode 270 are spaced apart from each other by a predetermined distance d in the region where the storage capacitor is formed such that the liquid crystal molecules may easily move. Accordingly, even if the storage capacitors are formed on the sub-spacers 320R, 320G, and 320B2, they do not influence the movement of the liquid crystal molecules, and particularly the generation of a region where the liquid crystal layer is not filled in the display area may be prevented and defects of the display characteristics may be prevented.

The present inventor compared the structure in which the storage electrode is formed at the same layer as the gate line with the structure according to an exemplary embodiment of the present invention, and as a result it was determined that an effect in which the aperture ratio is increased by 3.9% may be obtained in the structure according to an exemplary embodiment of the present invention compared with the conventional art.

Also, according to experimental results, when the capacitance between the storage electrode and the pixel electrode is 1 in the structure forming the storage electrode, the storage capacitance between the common electrode 270 and the pixel electrode 191B disposed at the sub-spacer 320B2 is about 1.14 in the structure according to an exemplary embodiment of the present invention, and accordingly it is confirmed that the storage capacitance is improved.

Accordingly, the aperture ratio is improved and the storage capacitance is increased in the liquid crystal display according to an exemplary embodiment of the present invention compared with the liquid crystal display of the conventional structure.

A manufacturing method of the liquid crystal display according to an exemplary embodiment of the present invention will be described with reference to FIG. 1 and FIG. 2.

Initially, a manufacturing method of the thin film transistor array panel 100 will be described.

A gate conductive layer (not shown) is deposited on an insulation substrate 110 and patterned by photolithography to form a gate line 121 including a gate electrode 124 and an end portion 129.

Next, a gate insulating layer 140 is formed on the gate line 121, and a semiconductor island 154 and ohmic contacts 163 and 165 are formed thereon.

A data conductive layer (not shown) is then deposited and patterned by photolithography to form a data line 171 including a source electrode 173 and an end portion 179, and a drain electrode 175.

A passivation layer 180 is formed on the data line 171 and the drain electrode 175 and patterned to form a plurality of contact holes 181, 182, and 185.

A pixel electrode 191 connected to the drain electrode 175 through the contact hole 185 is formed on the drain electrode 175. Finally, a first alignment layer 11 is formed on the pixel electrode 191.

Now, a manufacturing method of the common electrode panel 200 will be described.

A light blocking member (not shown) is formed on an insulation substrate 210, and color filters 230R, 230G, and 230B are formed on the substrate 210 and the light blocking member.

An overcoat layer (not shown) is then coated on the color filters 230R, 230G, and 230B.

The overcoat layer is ashed for surface treatment, and a photosensitive organic layer (not shown) is coated thereon.

Next, a mask is disposed on the photosensitive organic layer and the photosensitive organic layer is exposed to form a plurality of first spacers 320B1 and second spacers 320R, 320G, and 320B2. By ashing the overcoat layer, the adhesion between the overcoat layer and the first spacers 320B1 and the second spacers 320R, 320G, and 320B2 can be improved.

A common electrode 270 is then formed on the whole surface of the substrate including the first spacers 320B1 and the second spacers 320R, 320G, and 320B2, and the second alignment layer 21 is coated thereon.

The thin film transistor array panel 100 and the common electrode panel 200 are then combined.

Next, a liquid crystal is injected between the thin film transistor array panel 100 and the common electrode panel 200 to form a liquid crystal layer 3. This is not limiting, however, and a liquid crystal for the liquid crystal layer 3 may be dripped on the thin film transistor array panel 100 or the common electrode panel 200 before combining the thin film transistor array panel 100 and the common electrode panel 200.

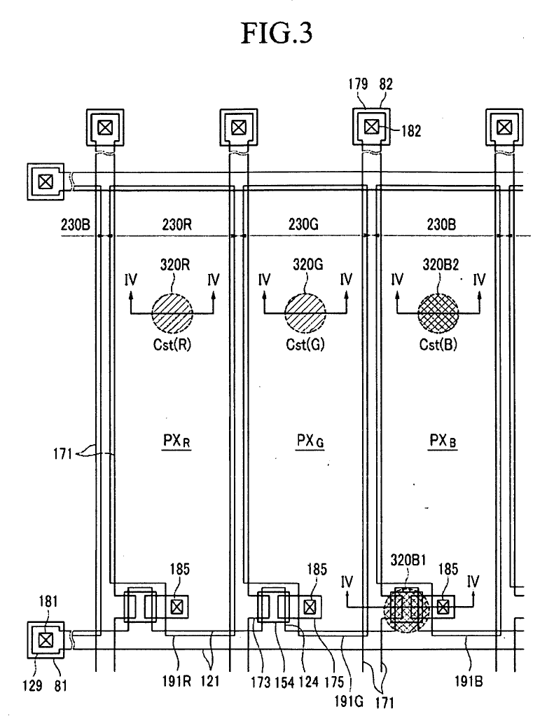

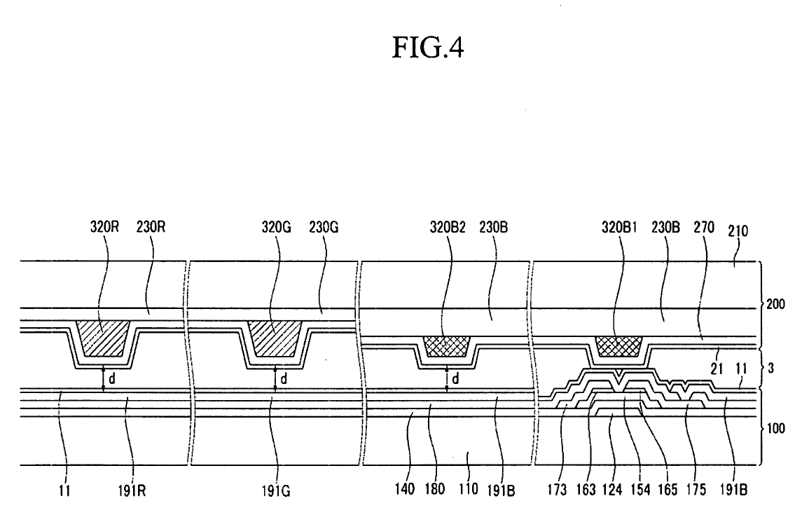

A liquid crystal display according to an exemplary embodiment of the present invention will now be described with reference to FIG. 3 and FIG. 4.

FIG. 3 is a layout view of a liquid crystal display according to an exemplary embodiment of the present invention, and FIG. 4 is a cross-sectional view of the liquid crystal display shown in FIG. 3 taken along the lines IV-IV.

Referring to FIG. 3 and FIG. 4, in a liquid crystal display according to the present exemplary embodiment, a color filter 230B of a blue pixel PX_{B} is thicker than respective color filters 230R and 230G of a red pixel PX_{R} and a green pixel PX_{G}, which differs from the above-described exemplary embodiment. This difference in thickness is to control the transmittance according to the wavelength of the light from the red pixel PX_{R}, the green pixel PX_{G}, and the blue pixel PX_{B}, wherein the transmittance is proportional to the cell gap and is inversely proportional to the wavelength such that the color filter 230B of the blue pixel PX_{B} is thicker so as to reduce the cell gap of the blue pixel PX_{B} having the short wavelength.

In this exemplary embodiment the main spacer 320B1 and the sub-spacer 320B2 disposed in the blue pixel PX_{B} have substantially the same height, and the sub-spacers 320R and 320G of the red pixel PX_{R} and the green pixel PX_{G} have substantially the same height.

Also, the main spacer 320B1 and the sub-spacer 320B2 disposed in the blue pixel PX_{B} have a smaller height than that of the sub-spacers 320R and 320G disposed in the red pixel PX_{R} and the green pixel PX_{G} As such, the color filter 230B of the blue pixel PX_{B} is thicker than the color filters 230R and 230G of the red pixel PX_{R} and the green pixel PX_{G} by a predetermined thickness, and the height of the sub-spacer 320B2 of the blue pixel PX_{B} is reduced by the predetermined thickness such that a distance d between the common electrode 270 and the pixel electrodes 191R, 191G, and 191B, which are disposed on the sub-spacers 320R, 320G, and 320B2 of each pixel PX_{R}, PX_{G}, and PX_{B}, may be maintained to be substantially the same. In this exemplary embodiment, the distance d may be in the range of about 0.1 to 0.3 μm.

The spacers 320R, 320G, 320B1, and 320B2 having the different heights may be formed by using a half-tone mask or a slit mask.

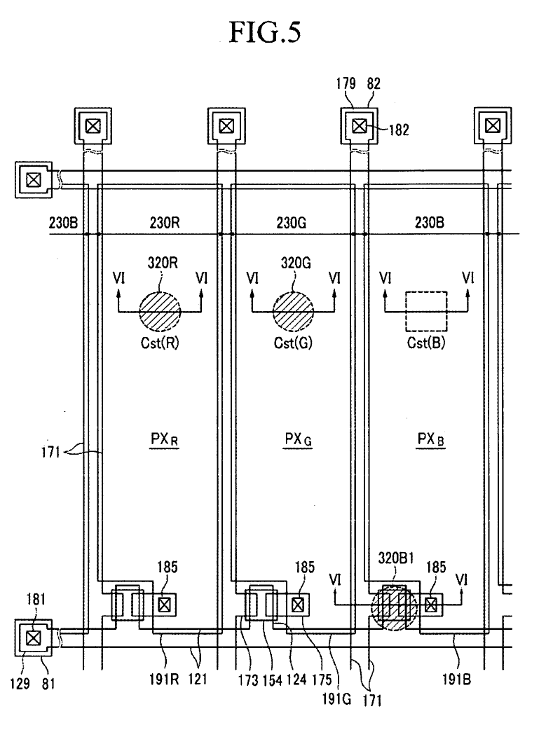

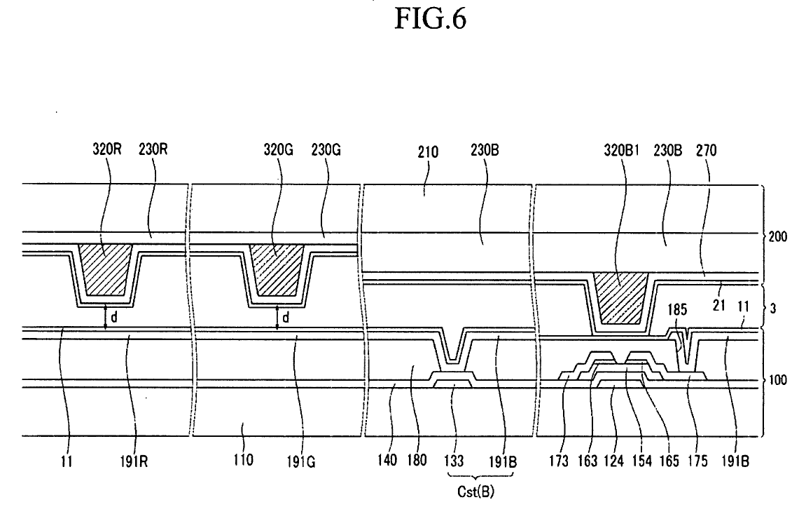

Next, a liquid crystal display according to an exemplary embodiment of the present invention will be described with reference to FIG. 5 and FIG. 6.

FIG. 5 is a layout view of a liquid crystal display according to another exemplary embodiment of the present invention, and FIG. 6 is a cross-sectional view of the liquid crystal display shown in FIG. 5 taken along the lines VI-VI.

Referring to FIG. 5 and FIG. 6, in a liquid crystal display according to the present exemplary embodiment, a main spacer 320B1 overlapping the thin film transistor is only formed in a blue pixel PX_{B}, and the sub-spacer 320B2 overlapping the pixel electrode 191B, as shown in FIGS. 1 and 3 does not exist, which differs from the above-described exemplary embodiment.

Like the above-described exemplary embodiment, the sub-spacers 320R and 320G disposed in the red pixel PX_{R} and the green pixel PX_{G} are formed, and the common electrode 270 and the pixel electrodes 191R and 191G that are disposed on the sub-spacers 320R and 320G are spaced apart from each other by the predetermined distance d. In this exemplary embodiment, the distance d may be in the range of about 0.1 to 0.3 μm. That is, storage capacitors Cst(R) and Cst(G) are formed in the red pixel PX_{R} and the green pixel PX_{G} at the portions where the sub-spacers 320R and 320G are disposed.

A storage electrode 133 that is at the same layer as the gate line 121 and overlaps the pixel electrode 191B is formed in the blue pixel PX_{B}, and a storage capacitor Cst(B) is formed between the storage electrode 133 and the pixel electrode 191B. In this exemplary embodiment, the passivation layer 180 on the storage electrode 133 is removed to increase the capacitance of the storage capacitor Cst(B).

The blue pixel PX_{B} is not limited thereto, however, and at least one pixel of the red pixel PX_{R} and the green pixel PX_{G} may form the storage capacitor through the storage electrode, and the remaining pixels may form the storage capacitor through the sub-spacer.

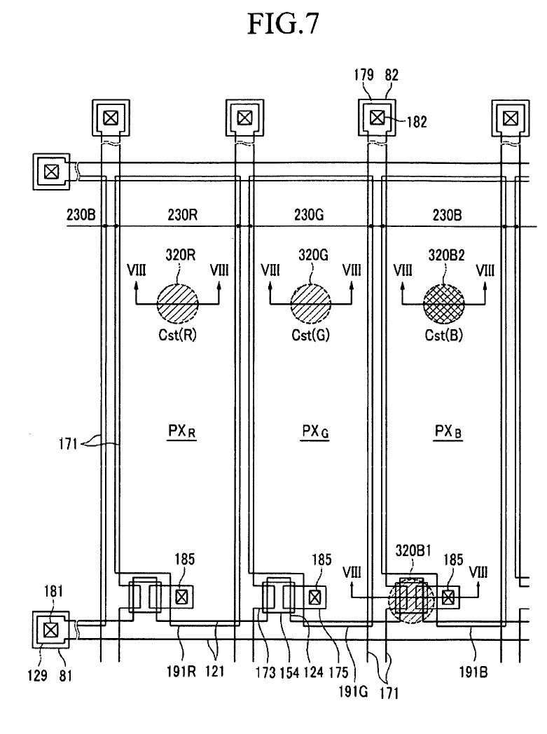

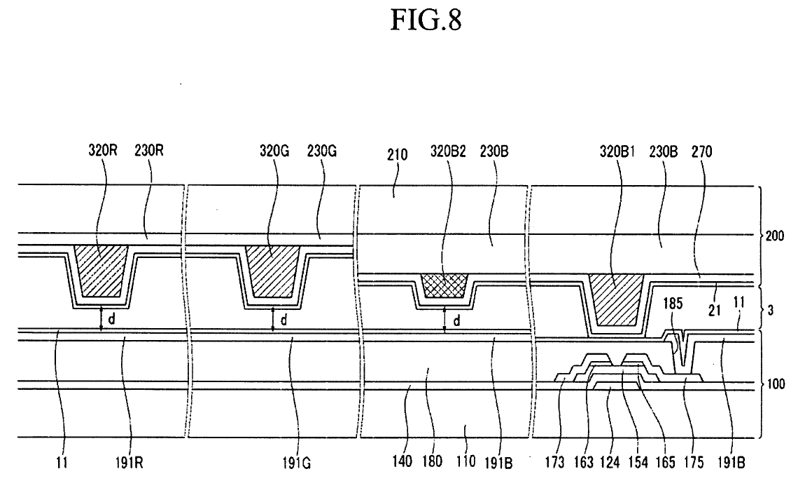

Next, a liquid crystal display according to an exemplary embodiment of the present invention will be described with reference to FIG. 7 and FIG. 8.

FIG. 7 is a layout view of a liquid crystal display according to an exemplary embodiment of the present invention, and FIG. 8 is a cross-sectional view of the liquid crystal display shown in FIG. 7 taken along the lines VIII-VIII.

Referring to FIG. 7 and FIG. 8, in a liquid crystal display according to the present exemplary embodiment, which differs from the above-described exemplary embodiment, a main spacer 320B1 and a sub-spacer 320B2 of a blue pixel PX_{B} have different heights. The color filter 230B of the blue pixel PX_{B} is thicker than the color filters 230R and 230G of the red pixel PX_{R} and the green pixel PX_{G} by a predetermined thickness, and the height of the sub-spacer 320B2 of the blue pixel PX_{B} is reduced by the predetermined thickness such that the distance d between the common electrode 270 and the pixel electrode 191R, 191G, and 19113, which are disposed on the sub-spacers 320R, 320G, and 320B2 of each pixel PX_{R}, PX_{G}, and PX_{B} may be maintained to be substantially the same. In this exemplary embodiment, the distance d may be in the range of about 0.1 to 0.3 μm. On the other hand, the main spacer 320B1 of the blue pixel PX_{B} has a greater height than the sub-spacer 320B2 such that the thin film transistor array panel 100 contacts the common electrode panel 200.

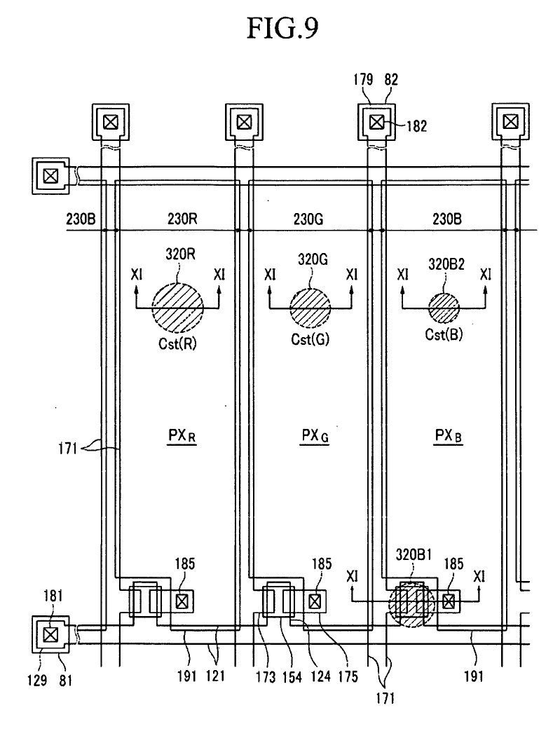

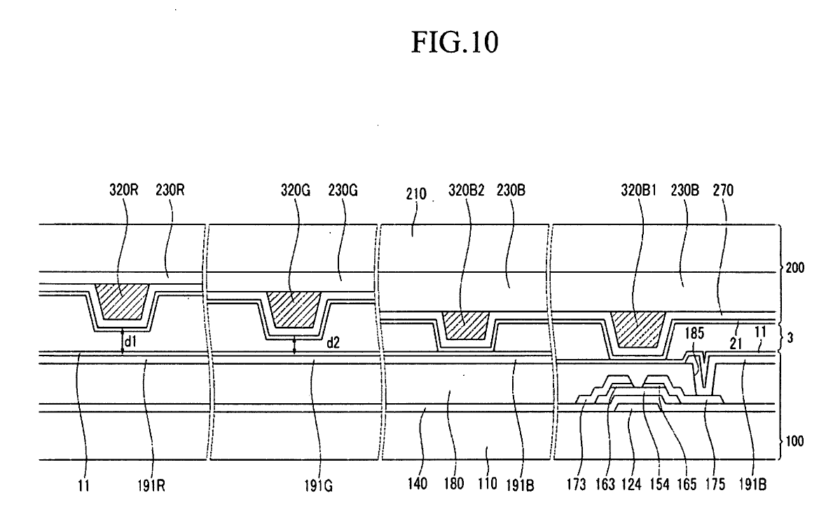

Next, a liquid crystal display according to an exemplary embodiment of the present invention will be described with reference to FIG. 9 and FIG. 10.

FIG. 9 is a layout view of a liquid crystal display according to an exemplary embodiment of the present invention, and FIG. 10 is a cross-sectional view of the liquid crystal display shown in FIG. 9 taken along the lines XI-XI.

Referring to FIG. 9 and FIG. 10, in a liquid crystal display according to the present exemplary embodiment, which differs from the above-described exemplary embodiment, color filters 230R, 230G, and 230B of a red pixel PX_{R}, a green pixel PX_{G}, and a blue pixel PX_{B}, respectively, have different thicknesses. This is to control the transmittance according to the wavelength of the light from the red pixel PX_{R}, the green pixel PX_{G}, and the blue pixel PX_{B}, and the transmittance is proportional to the cell gap and is inversely proportional to the wavelength such that the color filter 230B of the blue pixel PX_{B} having a short wavelength is thickest, and the color filter 230R of the blue pixel PX_{R} having a long wavelength is thinnest.

In this exemplary embodiment, the distances between the common electrode 270 and the pixel electrodes 191 that are disposed on the sub-spacers 320R, 320G, and 320B are different according to the thickness of the color filters 230R, 230G, and 230B. That is, the distance d1 between the common electrode 270 and the pixel electrode 191 that is disposed on the sub-spacer 320R in the red pixel PX_{R} is larger than the distance d2 between the common electrode 270 and the pixel electrode 191 that is disposed on the sub-spacer 320G of the green pixel PX_{G}. Also, the distance between the common electrode 270 and the pixel electrode 191 that is disposed on the sub-spacer 320R in the blue pixel PX_{B} is so small as to virtually not exist. In this case, the storage capacitances between the common electrode 270 and the various pixel electrodes 191 are different from each other.

In the present exemplary embodiment, the widths of the sub-spacers 320R, 320G, and 320B of each pixel are different such that a balance of the storage capacitance may be controlled. For example, in FIG-9 and FIG. 10, the blue filter 230B is thickest and the red filter 230R is thinnest among the color filters 230R, 230G, and 230B, however, the sub-spacer 320R of the red pixel is widest and the sub-spacer 320B2 in the blue pixel PX_{B} is narrowest among the sub-spacers 320R, 320G, and 320B2.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A liquid crystal display comprising:
a first substrate;
a thin film transistor formed on the first substrate;
a pixel electrode connected to the thin film transistor;
a second substrate facing the first substrate;
a first spacer formed on the second substrate, the first spacer overlapping the thin film transistor;
a second spacer formed on the second substrate, the second spacer overlapping the pixel electrode;
a common electrode formed on the second substrate, the first spacer, and the second spacer; and
a liquid crystal layer disposed between the first substrate and the second substrate,
wherein the pixel electrode and the common electrode disposed on the second spacer form a storage capacitor.

2. The liquid crystal display of claim 1, wherein
the pixel electrode and the common electrode disposed on the second spacer are spaced apart from each other by a distance in a range of 0.1 to 0.3 μm.

3. The liquid crystal display of claim 2, further comprising:
a first alignment layer formed on the pixel electrode; and
a second alignment layer formed on the common electrode,
wherein the first alignment layer contacts the second alignment layer disposed on the first spacer.

4. The liquid crystal display of claim 3, wherein
the liquid crystal display includes a first pixel, a second pixel and a third pixel, the pixels displaying different respective colors, and
the first spacer is formed in at least one pixel of the first pixel, the second pixel, and the third pixel.

5. The liquid crystal display of claim 4, wherein
the first pixel the second pixel, and the third pixel respectively include a first color filter, a second color filter, and a third color filter, and
at least one of the first color filter, the second color filter, and the third color filter has a different thickness from the other color filters.

6. The liquid crystal display of claim 5, wherein
the first color filter is the thickest, and
the second spacer of the first pixel has a smaller height than a height of the second spacers of the second pixel and the third pixel.

7. The liquid crystal display of claim 5, wherein
the first color filter is the thickest, and
the height of the second spacers of the first pixel, the second pixel and the third pixel are the same.

8. The liquid crystal display of claim 5, wherein
the first color filter, the second color filter, and the third color filter are progressively thicker, and
widths of the second spacers are progressively increased according to a sequence of the second spacer of the third pixel, the second spacer of the second pixel, and the second spacer of the first pixel.

9. The liquid crystal display of claim 4, wherein
one among the second spacers of the first pixel the second pixel, and the third pixel has a different height from the others.

10. The liquid crystal display of claim 4, wherein
the first pixel is a blue pixel, the second pixel is a green pixel, and the third pixel is a red pixel.

11. The liquid crystal display of claim 1, wherein
the liquid crystal display includes a first pixel, a second pixel, and a third pixel, the pixels displaying different respective colors, and
the first spacer is formed in at least one pixel of the first pixel the second pixel, and the third pixel.

12. The liquid crystal display of claim 11, wherein
the first pixel the second pixel and the third pixel respectively include a first color filter, a second color filter, and a third color filter, and
at least one of the first color filter, the second color filter, and the third color filter has a different thickness from the other color filters.

13. The liquid crystal display of claim 12, wherein
one among the second spacers of the first pixel the second pixel and the third pixel has a different height from the others.

14. A method for manufacturing a liquid crystal display comprising:
forming a thin film transistor and a pixel electrode on a first substrate;
forming a first spacer overlapping the thin film transistor and a second spacer overlapping the pixel electrode on the second substrate;
forming a common electrode on the first spacer and on the second spacer;
combining the first substrate and the second substrate; and
forming a liquid crystal layer between the first substrate and the second substrate.

15. The method of claim 14, wherein
the first spacer and the second spacer have different respective heights.

16. The method of claim 15, wherein
the first spacer and the second spacer are formed with the different heights by using halftone exposure or a slit mask.

17. The method of claim 14, further comprising
forming first, second, and third color filters on the second substrate before forming the first spacer and the second spacer,
wherein at least one of the first, second, and third color filters has a different thickness from the others.

18. The method of claim 17, wherein
the first color filter is the thickest and
the second spacers on the first, second, and third color filters have the same height.

19. The method of claim 17, wherein
the first color filter is the thickest,
the second spacer on the first color filter is formed with a different height from that of the second spacers on the second and third color filters.

20. The method of claim 17, wherein
the thickness becomes thicker in a sequence of the first color filter, the second color filter, and the third color filter, and
the width of the second spacers becomes larger in the sequence of the second spacer on the third color filter, the second spacer on the second color filter, and the second spacer on the first color filter.

21. The method of claim 17, wherein
the first color filter is a blue filter, the second color filter is a green filter, and the third color filter is a red filter.
